(19) United States
(12) Patent Application Publication
(10) Pub. No.: US 2006/0065893 A1
(43) Pub. Date: Mar. 30, 2006

(54) Method of forming gate by using layer-growing process and gate structure manufactured thereby

(75) Inventors: You-seung Jin, Seoul (KR); Shigenobu Maeda, Seongnam-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/233,806

(22) Filed: Sep. 23, 2005

(30) Foreign Application Priority Data
Sep. 24, 2004 (KR) 10-2004-0076910

(51) Int. Cl. H01L 29/10; H01L 21/3205

(52) U.S. Cl. 257/65; 257/412; 438/479; 438/488; 438/585

(57) ABSTRACT

Provided are a method of forming a gate by using layer growth, and a gate structure formed thereby. A gate dielectric layer and a seed layer are sequentially formed on a substrate, and then a mask is used to selectively grow a gate layer on the seed layer. An exposed portion of the seed layer surrounding the gate layer, and the gate layer, are isotropically etched to form a gate.

### BACKGROUND OF THE INVENTION

This application claims the benefit of Korean Patent Application No. 2004-7.6910, filed on Sep. 24, 2004, in the Korean Intellectual Property Office, the contents of which are incorporated herein in their entirety by reference.

1. Field of the Invention

The present invention relates to semiconductor device, and more particularly, to a method of forming a gate of a transistor with a small line width by using layer growth, and a gate structure formed thereby.

2. Description of the Related Art

When manufacturing a semiconductor device including a metal oxide semiconductor (MOS) transistor, the formation of a stable short channel transistor is regarded as a prerequisite for improving integrity of the semiconductor devices and performance of the transistor. However, in order to obtain a short channel, the size of a polycrystalline silicon bar of a gate must be minimized.

In order to obtain a minimized gate line width, lithography techniques and etching techniques for patterning the gate polycrystalline silicon must be improved. For example, due to resolution limit of lithography techniques, the gate polycrystalline silicon bar is not consistently extended, or line edge defects occur. These problems are more serious in non-planar transistors, such as fin field effect transistors (Fin FETs) and triple gate transistors.

FIG. 1 is a plan view of a line profile of a conventional gate.

Referring to FIG. 1, a gate 20 is formed on a semiconductor substrate 10. The gate 20 may include a polycrystalline silicon bar that has a small line width of about 50 nm. In this case, the bar of the gate 20 is not consistently extended, and/or has a rough edge profile.

In particular, the rough edge profile can be a more serious problem when, as is shown in FIG. 1, a groove 13 is formed in the semiconductor substrate 10 to expose sides of a channel 11. That is, in non-planar transistors, the gate 20 may have a rough line profile due to an underlying non-planar semiconductor substrate 10. Even in planar transistors, the gate 20 may have a rough line profile due to a small line width.

In detail, the rough line profile of the gate 20 results mainly from a resolution limit of a lithography process for patterning the gate and/or a limit of subsequent etching. Conventionally, in the lithography process, an ArF light source is used for exposure. However, when the lithography and the subsequent etching are used to pattern the gate 20 having a line width less than 50 nm, the ArF light cannot be directly used because the ArF light has a wavelength of about 193 nm.

Therefore, after the lithography process, an exposed and developed photoresist pattern is trimmed to reduce a line width of an etch mask to a desired level. In this case, however, photoresist erosion and/or the formation of a rough profile cannot be avoided. Therefore, when a non-planar transistor is manufactured, much pitting occurs in the active region when the gate 20 is etched.

Besides the rough line profile of the gate 20, active pitting also occurs in an active region when dry etching is performed. In detail, the active pitting occurs when the gate 20 is patterned by dry etching, and particularly, more seriously when surface steps are formed below the gate.

In addition, when the gate 20 is patterned by dry etching, and when an N-type gate is doped with an N-type dopant and a P type gate is doped with a P-type dopant, the critical dimension (CD) between the N-type gate and the P-type gate may be large. This problem occurs when a dopant doped on polycrystalline silicon affects, for example, a dry etch speed. In order to solve this problem, some changes must be made to, for example, a design or an exposure process.

The dry etch damage may be prevented by using a damascene process to form the gate 20. In the damascene process, first, a dummy damascene pattern is formed. Next, a polycrystalline silicon layer is deposited. Then, the polycrystalline silicon layer is polished by chemical mechanical polishing (CMP). Finally, the dummy damascene pattern is removed to form a gate.

However, since a damascene process includes the CMP process, a large portion of the polycrystalline silicon layer can be torn. In addition, dishing may occur in the polysilicon layer. Further, variations in the CMP may occur in a chip or a wafer, or between wafers.

These problems must be solved to have a short-channel transistor in order to increase the integrity of semiconductor devices and the performance of transistors.

### SUMMARY OF THE INVENTION

The present invention provides a method of forming a gate, and a gate structure formed thereby. According to the method, a gate with a small line width can be provided with an improved line profile, and problems resulting from chemical mechanical polishing (CMP) can be prevented.

According to an aspect of the present invention, there is provided a method of forming a gate of a transistor. According to the method, a gate dielectric layer is formed on a substrate, and a seed layer is formed on the gate dielectric layer. A mask is formed on the seed layer to selectively grow a gate layer. The gate layer is selectively grown on a portion of the seed layer exposed by the mask. The mask is selectively removed, and the exposed portions of the seed layer and the gate layer are isotropically etched to form a gate, such that the gate has a smaller line width compared to the gate layer.

After a mask having an open region exposing a portion of the seed layer is formed, spacers covering a portion of the exposed portion of the seed layer are formed on sidewalls of the open region of the mask. Therefore, a line width of the exposed portion of the seed layer is less than an upper line width of the open region. As a result, a lower line width of the gate may be less than a line width of the gate layer and an upper line width of the gate is greater than the lower line width of the gate.

The seed layer may be formed of polycrystalline silicon.

The seed layer may be formed of silicon germanium.

The seed layer may have a thickness of a few to few tens nanometers.

The mask and/or the spacer may be formed of a silicon oxide, Si₃N₄, or SiON.

The gate layer may be formed by epitaxtially growing polycrystalline silicon on the seed layer.

The gate layer may be formed by epitaxtially growing silicon germanium on the seed layer.

The gate may be formed using isotropic etch, wherein the isotropic etch is chemical dry etch (CDE).

The gate may be formed using an isotropic etch, wherein the isotropic etch is dry etch or wet etch.

According to another aspect, the invention is directed to a method of forming a gate of a transistor. According to the method, a gate dielectric layer is formed on a substrate, and a seed layer is formed on the gate dielectric layer. A mask having an open region exposing a portion of the seed layer is formed on the seed layer to selectively grow a gate layer on the exposed portion of the seed layer. Spacers covering a portion of the exposed portion of the seed layer are formed on sidewalls of the open region of the mask such that a line width of the exposed portion of the seed layer is less than an upper line width of the open region. The gate layer is selectively grown on the portion of the seed layer exposed by the mask and the spacer. The mask and the spacer are selectively removed. Exposed portions of the seed layer and the gate layer are isotropically etched to form a gate such that a lower line width of the gate is less than a line width of the gate layer and an upper line width of the gate is greater than the lower line width of the gate.

The seed layer may be formed of polycrystalline silicon.

The seed layer may be formed of silicon germanium.

The mask and/or the spacer may be formed of a silicon oxide, Si₃N₄, or SiON.

The spacer and the mask may be formed of identical insulating materials.

The gate layer may be formed by epitaxtially growing polycrystalline silicon on the seed layer.

The gate layer may be formed by epitaxtially growing silicon germanium on the seed layer.

The gate may be formed by chemical dry etching (CDE).

According to another aspect, the invention is directed to a gate of a transistor. The gate includes a seed layer formed on a gate dielectric layer on a substrate and a gate layer formed by selectively growing silicon germanium on the seed layer.

According to another aspect, the invention is directed to a gate of a transistor. The gate includes a seed layer formed on a gate dielectric layer on a substrate, and a gate layer formed by selectively growing silicon germanium on the seed layer. According to the invention, a lower line width of the gate layer is less than an upper line width of the gate layer.

In one embodiment, the seed layer is formed of polycrystalline silicon.

A gate manufactured in the above-mentioned method has a substrate, a gate dielectric layer, a seed layer, and a gate layer sequentially formed. The gate layer is formed by growing silicon germanium on the seed layer. In accordance with the invention, a lower line width of the gate layer is less than an upper line width of the gate layer.

According to the present invention, when a gate with a small line width is formed, a gate line profile can be improved. In addition, problems resulting from CMP can be prevented due to the omission of the CMP.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. In the drawings, the thickness of layers and regions are exaggerated for clarity. The drawings are not necessarily to scale, emphasis instead being placed upon illustrating the principles of the invention.

FIG. 1 is a top plan view of a line profile of a conventional gate.

FIG. 2 is a sectional view illustrating a step of defining an active region according to an embodiment of the present invention.

FIG. 3 is a sectional view illustrating a step of forming a gate dielectric layer in the active region according to an embodiment of the present invention.

FIG. 4 is a sectional view illustrating a step of forming a seed layer according to an embodiment of the present invention.

FIG. 5 is a sectional view illustrating a step of forming a mask layer according to an embodiment of the present invention.

FIG. 6 is a sectional view illustrating a step of forming a photoresist pattern according to an embodiment of the present invention.

FIG. 7 is a sectional view illustrating a step of forming a mask by patterning the mask layer according to an embodiment of the present invention.

FIG. 8 is a sectional view illustrating a step of removing a phoresist pattern formed on the mask according to an embodiment of the present invention.

FIG. 9 is a sectional view illustrating a step of selectively growing a gate layer using the mask according to an embodiment of the present invention.

FIG. 10 is a sectional view illustrating a step of selectively removing the mask according to an embodiment of the present invention.

FIG. 11 is a sectional view illustrating a step of forming a gate by reducing the gate layer according to an embodiment of the present invention.

FIG. 12 is a sectional view illustrating a step of forming a spacer on sidewalls of the mask according to an embodiment of the present invention.

FIG. 13 is a sectional view illustrating a step of growing a mushroom-like gate layer according to an embodiment of the present invention.

FIG. 14 is a sectional view illustrating a step of removing the spacer according to an embodiment of the present invention.

FIG. 15 is a sectional view illustrating a step of reducing the mushroom-like gate layer to form a gate according to an embodiment of the present invention.

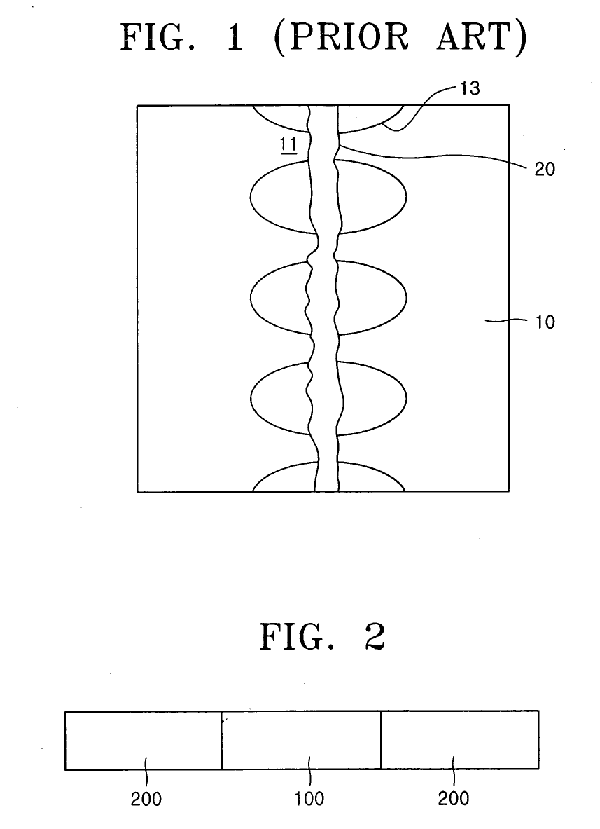

### DETAILED DESCRIPTION OF THE INVENTION

The present invention will now be described more fully with reference to the accompanying drawings, in which exemplary embodiments of the invention are shown. Throughout the description, when a layer is described as being formed on another layer or on a substrate, the layer may be formed on the other layer or on the substrate, or a third layer may be interposed between the layer and the other layer or the substrate.

In embodiments of the present invention, a damascene process is used to form a gate with a small line width, and a silicon layer or a silicon germanium (SiGeₓ) layer is selectively grown to a dummy damascene pattern. In this case, dry etching and chemical mechanical polishing (CMP) are not used when a gate is patterned. Therefore, problems caused by the use of dry etching or CMP can be prevented.

In addition, trimming of a photoresist pattern is not used, and the silicon layer and/or the SiGeₓ layer selectively grown can be isotropically etched. Therefore, a line width of the gate is less than a line width defined by a mask pattern.

FIGS. 2 through 11 are sectional views illustrating a method of forming a gate according to an embodiment of the present invention.

Referring to FIG. 2, a field region 200 defining an active region 100 in a semiconductor substrate is formed. The semiconductor substrate may be a bulk silicon substrate or a silicon-on-insulator (SOI) substrate. The field region 200 is formed by a device isolation process and may be composed of an insulating material, such as a silicon oxide.

The active region 100 may be a semiconductor layer, such as a silicon layer. The active region 100 is used to form a channel of a transistor and a source/drain region. Therefore, when a planar transistor is to be formed, the active region 100 may have a planar surface. However, when a non-planar transistor is to be formed, the active region 100 may have a three-dimension structure. For example, a groove can be formed in the active region 100 or the active region 100 can be patterned to expose a side surface or a bottom surface as well as an upper surface of a channel.

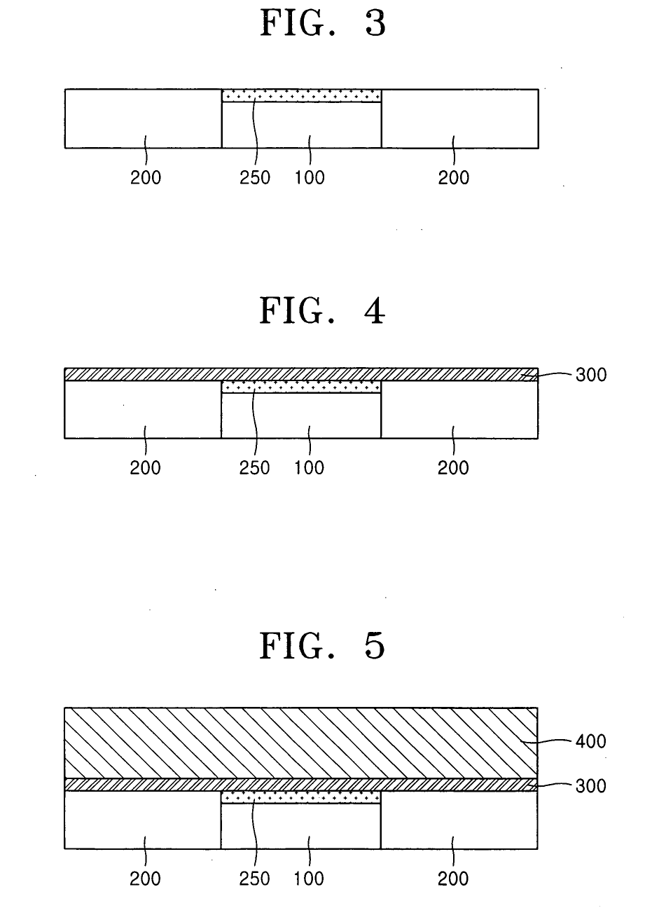

Referring to FIG. 3, a gate dielectric layer 250 is formed in the active region 100 by oxidizing a surface of the active region 100. Therefore, the gate dielectric layer 250 is composed of an oxide. The gate dielectric layer 250 may be formed using, for example, chemical vapor deposition (CVD).

Referring to FIG. 4, a seed layer 300 on which a gate layer will be grown is formed. A gate of a transistor may be formed using various methods. For example, in the present embodiment, the gate is formed by sequentially growing layers, using, for example, epitaxial growth. Therefore, the seed layer 300 is formed because it is required to grow the gate layer.

For example, when the gate layer is a conductive polycrystalline silicon layer, a silicon germanium layer or a composite layer of polycrystalline silicon and silicon germanium layers, the seed layer 300 may be a silicon layer such that one of these silicon layers can be epitaxially grown. Since the gate is substantially composed of polycrystalline silicon, the seed layer 300 can be formed by depositing a polycrystalline silicon layer. Alternatively, the seed layer 300 can be a silicon germanium layer. In this case, the silicon germanium layer is formed by doping a silicon layer with germanium.

The seed layer 300 may have a thickness between a few or a few tens of nanometers. Preferably, the seed layer 300 is as thin as possible.

Referring to FIG. 5, a mask layer 400 is formed on the seed layer 300 to selectively grow the gate layer. The mask layer 400 will be used to form a mask pattern. The mask pattern induces the gate layer to be selectively grown with a predetermined pattern.

Therefore, the mask layer 400 is composed of an insulating material to be selectively removed with respect to a grown gate layer. The insulating material may be Si₃N₄, SiON, a silicon oxide, or the like. The mask layer 400 may be thicker than the seed layer 300.

Referring to FIG. 6, a photoresist pattern 500 for patterning the mask layer 400 is formed. To pattern the mask layer 400 for selectively growing the gate layer, the mask layer 400 is covered with a photoresist layer, and then lithography is performed to pattern the photoresist pattern 500. The photoresist pattern 500 may be used as the etch mask to pattern the mask layer 400.

An open region exposed by the photoresist pattern 500 is a location or a region for a gate. The photoresist can be a negative photoresist or a positive photoresist. The lithography process used to form the photoresist pattern 500 may be a conventional lithography process for patterning a gate. That is, the photoresist pattern 500 can be exposed using a reticle, which is used in conventional gate patterning. Thus, a new reticle is not required.

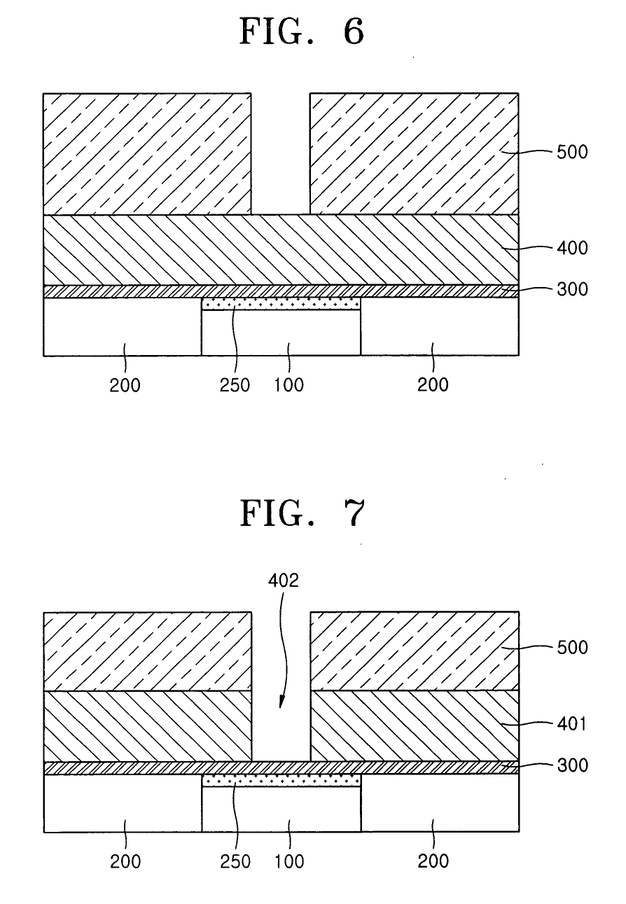

Referring to FIG. 7, a portion of the mask layer 400 on which the gate layer is to be selectively grown is exposed by the photoresist pattern 500. The exposed portion of the mask layer is selectively removed to form a mask 401. The mask 401 has an open region 402 exposing a portion of the seed layer 300 on which the gate layer will be grown.

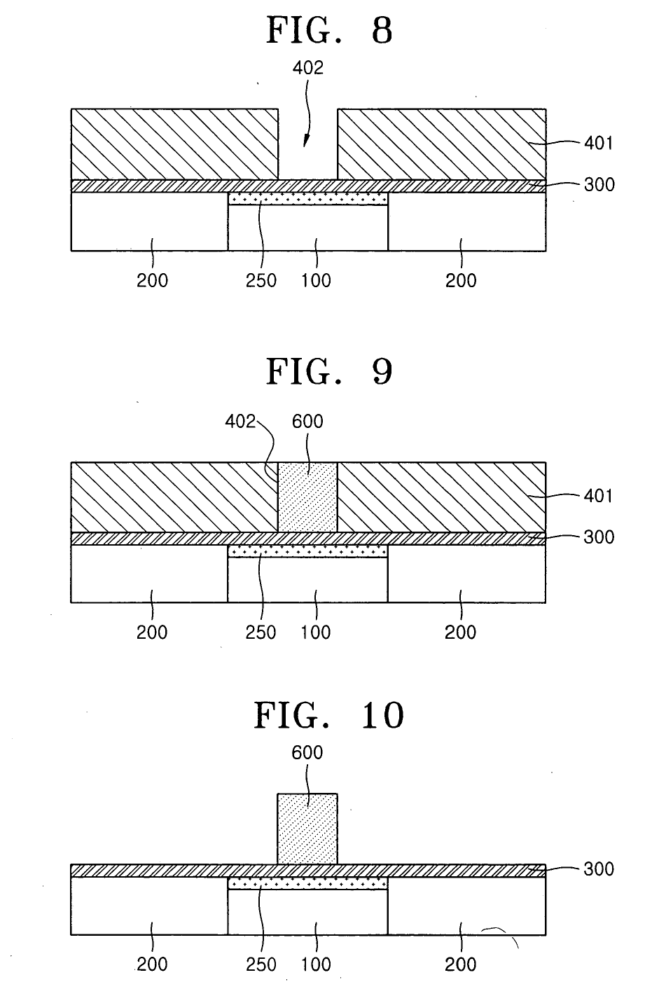

Referring to FIG. 8, the residual photoresist pattern 500 after being used as the etch mask is selectively removed using, for example, ashing or stripping.

Referring to FIG. 9, a silicon layer or a silicon germanium layer is grown on a surface of the portion of the seed layer 300 exposed by the open region 402 to form a gate layer 600 that fills the open region 402. The gate layer 600 can be formed by optional epitaxital growth. Since the mask 401 is composed of Si₃N₄ or SiON, the mask 401 functions as a growth preventing layer to inhibit the growth of the silicon layer or the silicon germanium layer when the eptiaxial growth is performed.

Such growth of the silicon layer or the silicon germanium layer is adjusted such that the gate layer 600 fills the open region 402. The size of the gate layer 600 may vary according to the size of a transistor to be formed. For example, the gate layer 600 may have a thickness of about 800 to 1500 Å.

The growth of the silicon layer or the silicon germanium layer on the mask 401 is selectively inhibited. Therefore, an additional etching process for patterning a grown layer, a lithography process accompanying the etching process, a CMP process, or the like can be avoided. If a CMP process is performed, the CMP process is performed subsequent to the lithography process. Therefore, many problems that occur when a gate is formed using a conventional damascene process such as surface tear or dishing of the polycrystalline silicon layer, CMP variation, and the like are overcome.

In addition, after the gate layer 600 is grown, conventional anisotropic dry etching for patterning the grown gate 600 can be omitted. Therefore, problems resulting from conventional anisotropic dry etching, such as active pitting, a rough etch profile, or the like, can be prevented.

Further, since the gate layer 600 is selectively formed by epitaxital growth, patterning by dry etching can be omitted. The omitting of the dry etching results in improvements in a gate profile of non-planar transistors, such as fin field effect transistors (FinFETs) or triple gate transistors, as well as in planar transistors. Further, the gate profile can be further improved by omission of a conventional PR trimming process. In addition, the omission of the dry etch process prevents a phenomenon in which N/P polycrystalline silicon gates have different gate profiles and critical dimensions (CD).

Referring to FIG. 10, after the gate layer 600 is selectively grown, the mask 401 used for the optional growth is removed by dry etching or wet etching. Since the gate layer 600 is composed of polycrystalline silicon or silicon germanium, the mask 401 composed of Si₃N₄, or SiON can be removed using a known optional etching method. Therefore, both sides of the gate layer 600 and a surface of the underlying seed layer 300 are exposed.

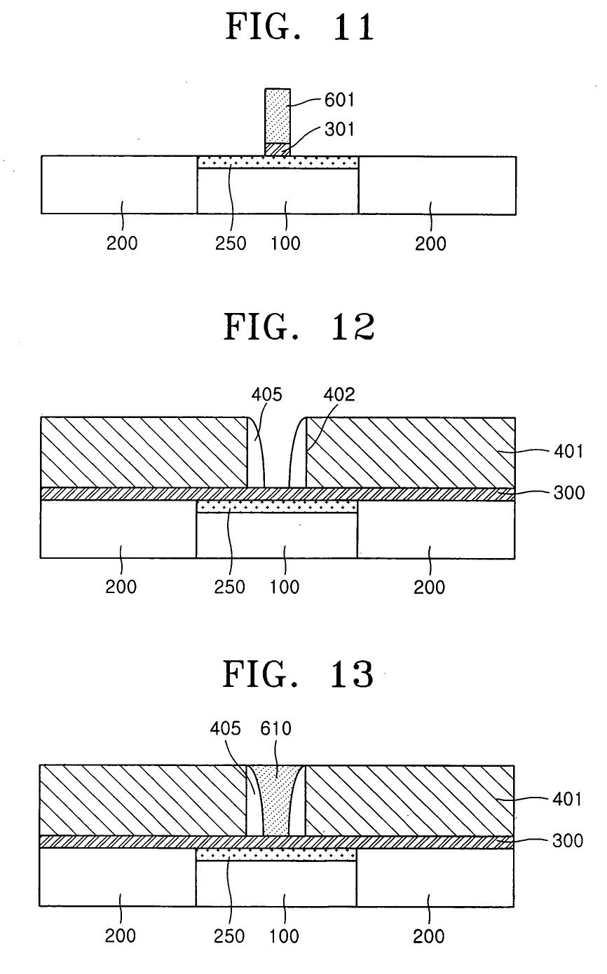

Referring to FIG. 11, the gate layer 600 and the exposed surface of the seed layer 300 are isotropically etched to form a gate layer pattern 601 with a smaller line width than the gate layer 600. The etching is dry etching or wet etching, but is not anisotropic etching in order to minimize damage to the underlying active region 100 and/or the gate dielectric layer 250. For example, chemical dry etching (CDE) may be performed.

CDE uses a chemical reaction of an etchant, which has a high etch selectivity for silicon with respect to a silicon oxide. The etchant may be CF₄, O₂, or the like. When the CDE is performed, physical etching, including ion acceleration, does not occur such that underlying layers, such as the gate dielectric layer 250 and/or the active region 100, can be protected. In the CDE, since the etch selectivity of polycyrstaline silicon to silicon oxide is about 102:1, the gate dielectric layer 250 and/or the underlying active region 100 can be effectively protected.

The CDE is performed on the exposed entire surface of the gate layer 600. That is, the exposed sides as well as an exposed upper surface of the gate layer 600 are etched such that the gate layer pattern 601 has a smaller line width than the gate 600. When the photoresist trimming process is omitted, the gate layer 600 may be selectively formed to a line width of about 80 nm. In this case, the line width is limited by the lithography process and the mask used. However, the use of CDE allows the gate layer pattern 601 to have a line width of less than 40 nm.

When the CDE is performed, the exposed portion of the seed layer 300 surrounding the gate layer 600 is also selectively removed to form the seed layer pattern 301 interposed between the gate layer pattern 601 and the gate dielectric layer 250. As a result, the gate 301 and 601 are formed.

The gate 301 and 601 has a line width of, for example, about less than 40 nm, and an excellent line profile. After the gate 301 and 601 is formed, the remaining manufacturing processes for forming the transistor are performed conventionally to form a planar-transistor and/or a non-planar transistor.

When the gate 301 and 601 is composed of the polycrystalline silicon, a problem relating to the formation and expansion of a depletion layer formed inside the gate occurs. However, when the gate layer pattern 601 and/or the seed layer pattern 301 comprising the gate 301 and 601 are composed of silicon germanium, such a problem can be prevented.

When a line width of the gate 301 and 601 is in the range of about less than 50 to 60 nm, a problem may occur when a specific silicide layer may be formed on a surface of the gate 301 and 601. For example, when an underlying silicon layer has a line width of about less than 50 to 60, an upper surface of a gate is reduced. As a result, a CoSiₓ layer formed on the gate has an increased resistance due to agglomeration therein. In addition, when the line width of the gate is reduced too much, the upper surface of the gate is reduced and fails to contact a connecting contact.

Such a problem can be overcome by providing a gate with a wider upper line width of the gate than a lower line width contacting the gate dielectric layer. Such a gate can be formed according to another embodiment of the present invention, which is illustrated in FIGS. 12 through 15.

Referring to FIG. 12, a spacer 405 is formed on sidewalls of a mask 401 for selective growth of a gate layer. As illustrated in FIGS. 2 through 7, the mask 401 is formed for selectively growing a gate layer, and then the spacer 405 is formed on sidewalls of the mask 401 using a spacer process. The spacer 405 may be composed of an insulating material. Since the spacer 405 may be removed in the subsequent process, the spacer 405 and the mask 401 may be composed of identical insulating materials. The insulating material may be Si₃N₄, SiON, or the like.

Because of the spacer 405, the entrance width of the open region 402 is broader than the bottom width of the open region 402 exposing a surface of a seed layer 300.

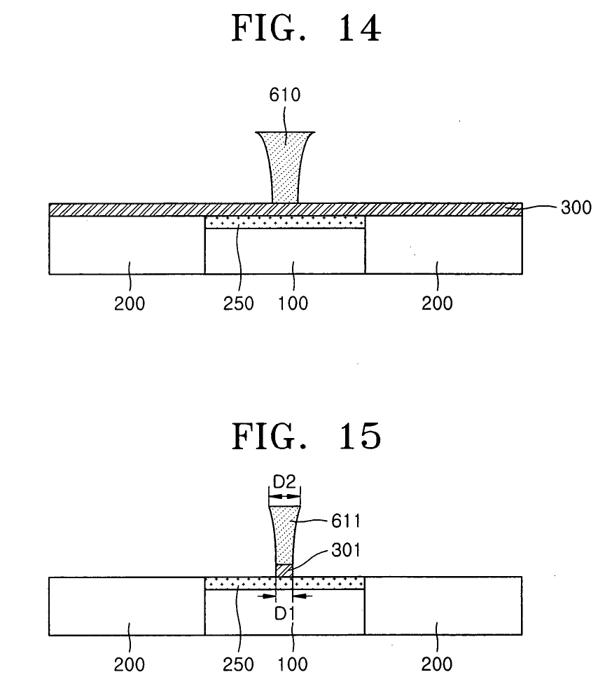

Referring to FIG. 13, as with the operation illustrated in FIG. 9, a silicon layer or a silicon germanium layer is grown on a portion of the seed layer 300 exposed by the spacer 405 to form a gate layer 610 filling the open region 402. The gate layer 610 may be formed by selective epitaxtial growth.

The gate layer 610 has sidewalls having a shape corresponding to a convex sidewall profile of the spacer 405 formed on a sidewall of the mask 401. For example, the gate layer 610 can have concave sidewalls. In addition, an upper line width of the gate layer 610 is greater than a lower line width of the gate layer 610 contacting the seed layer 300. That is, the gate layer 610 has a mushroom-like sectional view.

Referring to FIG. 14, after the gate layer is selectively grown, as with the operation illustrated in FIG. 10, the mask 401 is removed by dry etching or wet etching. In addition, the spacer 405 is selectively removed to expose both sidewalls of the gate layer 610 and a surface of the underlying seed layer 300.

Referring to FIG. 15, the gate layer 600 and the exposed portion of the seed layer 300, as with the operation illustrated in FIG. 11, are istropically etched to form a gate layer pattern 601 with a small line width compared to the width of the gate layer 600. That is, CDE is performed to form a gate layer pattern 611 and a seed layer pattern 301.

In one embodiment, each of a lower line width of the gate layer pattern 611 and a line width D1 of the seed layer pattern 301 is less than a line width D2 of an upper surface of the gate layer pattern 611. For example, D1 may be less than about 40 nm, and D2 may be at least 60 nm.

Therefore, problems occurring when a silicide layer is formed on a surface of a gate so as to decreases resistance can be prevented. Such a low resistance is required for a transistor, such as a logic circuit, or an SRAM, that operates rapidly. That is, when the upper line width of the gate 301 and 611 is reduced, agglomeration occurs inside a silicide layer, such as a CoSiₓ layer. However, in the present embodiment, the agglomeration can be effectively prevented due to the mushroom-like gate layer. In addition, the upper surface of the gate 301 and 611 is large enough to contact the connecting contact.

According to the present invention, a gate can be scaled down without photoresist (PR) trimming. Therefore, PR erosion caused by PR trimming can be prevented. Further, an inconsistent gate line, a surface tear, a rough edge profile, or the like which all results from PR erosion can be prevented. In addition, when a gate is formed from a polycrystalline silicon layer, CMP is not required. Therefore, a surface tear of the polycrystalline silicon layer, dishing, CMP variation can be avoided.

When a gate is selectively grown, the gate is automatically patterned. Therefore, anisotropic dry etching is not required to pattern the gate. The omission of the anisotropic dry etching results in the prevention of active pitting, which occurs when the polycrystalline silicon layer used to produce the gate is etched. In addition, when a non-planar transistor or a planar transistor is formed, a profile of a gate line can be improved. That is, the underlying surface topology does not bring defects. In addition, N/P polycystalline silicons have identical gate profiles and CDs.

Further, a mask used to optionally grow a gate layer is patterned using a reticle, which is also used to pattern a conventional gate polycrystalline silicon layer. Therefore, a new reticle is not required in the present invention.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of forming a gate of a transistor, the method comprising:
forming a gate dielectric layer on a substrate;
forming a seed layer on the gate dielectric layer;
forming a mask on the seed layer to selectively grow a gate layer;
selectively growing the gate layer on a portion of the seed layer exposed by the mask;
selectively removing the mask; and
isotropically etching exposed portions of the seed layer and the gate layer to form a gate such that the gate has a smaller line width than the gate layer.

2. The method of claim 1, wherein the seed layer comprises polycrystalline silicon.

3. The method of claim 1, wherein the seed layer comprises silicon germanium.

4. The method of claim 1, wherein the seed layer has a thickness of a few to a few tens of nanometers.

5. The method of claim 1, wherein the mask comprises at least one of silicon oxide, Si₃N₄, and SiON.

6. The method of claim 1, wherein the gate layer is formed by epitaxtially growing polycrystalline silicon on the seed layer.

7. The method of claim 1, wherein the gate layer is formed by epitaxtially growing silicon germanium on the seed layer.

8. The method of claim 1, wherein the gate is formed by chemical dry etching-(CDE).

9. The method of claim 1, wherein the gate is formed by at least one of dry etching and wet etching.

10. A method of forming a gate of a transistor, the method comprising:
forming a gate dielectric layer on a substrate;
forming a seed layer on the gate dielectric layer;
forming on the seed layer a mask having an open region exposing a portion of the seed layer to selectively grow a gate layer on the exposed portion of the seed layer;
forming spacers covering a portion of the exposed portion of the seed layer on sidewalls of the open region of the mask such that a line width of the exposed portion of the seed layer is less than an upper line width of the open region;
selectively growing the gate layer on the portion of the seed layer exposed by the mask and the spacer;
selectively removing the mask and the spacer; and
isotropically etching exposed portions of the seed layer and the gate layer to form a gate such that a lower line width of the gate is less than a line width of the gate layer and an upper line width of the gate is greater than the lower line width of the gate.

11. The method of claim 10, wherein the seed layer comprises polysilicon silicon.

12. The method of claim 10, wherein the seed layer comprises silicon germanium.

13. The method of claim 10, wherein the mask comprises at least one of silicon oxide, Si₃N₄, and SiON.

14. The method of claim 13, wherein the spacer and the mask are formed of identical insulating materials.

15. The method of claim 10, wherein the gate layer is formed by epitaxtially growing polycrystalline silicon on the seed layer.

16. The method of claim 10, wherein the gate layer is formed by epitaxtially growing silicon germanium on the seed layer.

17. The method of claim 10, wherein the gate is formed by chemical dry etching (CDE).

18. A gate of a transistor, the gate comprising:
a seed layer formed on a gate dielectric layer on a substrate; and
a gate layer formed by selectively growing silicon germanium on the seed layer.

19. A gate of a transistor, the gate comprising:
a seed layer formed on a gate dielectric layer on a substrate; and
a gate layer formed by selectively growing silicon germanium on the seed layer, wherein a lower line width of the gate layer is less than an upper line width of the gate layer.

20. The gate of claim 19, wherein the seed layer is formed of polycrystalline silicon.
